(19) United States
(12) Patent Application Publication
(10) Pub. No.: US 2016/0307920 A1
(43) Pub. Date: Oct. 20, 2016

(54) DISPLAY PANEL AND MANUFACTURING METHOD THEREOF

(71) Applicant: E Ink Holdings Inc., Hsinchu (TW)

(72) Inventors: Jia-Hung Chen, Hsinchu (TW); Kuang-Heng Liang, Hsinchu (TW); Shu-Fen Tsai, Hsinchu (TW); Yao-Te Tseng, Hsinchu (TW)

(21) Appl. No.: 14/825,188

(22) Filed: Aug. 13, 2015

(30) Foreign Application Priority Data
Apr. 15, 2015 (TW) 104112059

(51) Int. Cl. H01L 27/12; G02F 1/167; G02F 1/1362; G02B 26/00

(52) U.S. Cl. CPC H01L 27/124; H01L 27/1262; G02B 26/005; G02F 1/167; G02F 1/136286

(57) ABSTRACT

A display panel includes an array substrate, a plurality of transparent conductive oxide patterns, and a display medium. The array substrate includes a substrate, and a first metal layer, a first insulation layer, a semiconductor layer, a second metal layer, and a second insulation layer sequentially disposed on the substrate. The substrate has an active region and a wiring region. The first metal layer and the second metal layer extend from the active region to the wiring region to respectively define a plurality of first wirings and second wirings. The transparent conductive oxide patterns are disposed on the second insulation layer in the wiring region to respectively correspond to the second wirings. An orthogonal projection of each of the transparent conductive oxide patterns onto the substrate overlaps with an orthogonal projection of the corresponding second wiring onto the substrate. The display medium is disposed on the array substrate.

### CROSS-REFERENCE TO RELATED APPLICATION

This application claims the priority benefit of Taiwan application serial no. 104112059, filed on Apr. 15, 2015. The entirety of the above-mentioned patent application is hereby incorporated by reference herein and made a part of this specification.

### BACKGROUND OF THE INVENTION

1. Field of the Invention

The invention relates to a display panel and a manufacturing method thereof, and in particular, a display panel and a manufacturing method thereof with higher reliability.

2. Description of Related Art

In current panel layout designs, an array substrate of a display panel mostly uses a single-layer circuit structure in a fan-out region at a terminal side. Therefore, if a hole is formed in a protection layer covering fan-out conductive lines due to a process variation, the fan-out conductive lines that are most adjacent to the protection layer will be exposed to the atmosphere and further oxidized or eroded, which in turn affects structural reliability of the display panel as a whole.

### SUMMARY OF THE INVENTION

The invention provides a display panel and a manufacturing method thereof having improved structural reliability.

The display panel of the invention includes an array substrate, a plurality of transparent conductive oxide patterns, and a display medium. The array substrate includes a substrate, and a first metal layer, a first insulation layer, a semiconductor layer, a second metal layer, and a second insulation layer sequentially disposed on the substrate. The substrate has an active region and a wiring region at a periphery of the active region. The first metal layer and the second metal layer extend from the active region to the wiring region to respectively define a plurality of first wirings and a plurality of second wirings. The transparent conductive oxide patterns are disposed on the second insulation layer and located in the wiring region, wherein the transparent conductive oxide patterns respectively correspond to the second wirings. An orthogonal projection of each of the transparent conductive oxide patterns onto the substrate overlaps with an orthogonal projection of the corresponding second wiring onto the substrate. The display medium is disposed on the array substrate.

In one embodiment of the invention, the transparent conductive oxide patterns are not connected to each other.

In one embodiment of the invention, a material of the transparent conductive oxide patterns is indium tin oxide or indium zinc oxide.

In one embodiment of the invention, an extension direction of each of the transparent conductive oxide patterns is identical to an extension direction of the corresponding second wiring.

In one embodiment of the invention, a width of the orthogonal projection of each of the transparent conductive oxide patterns onto the substrate is greater than a line width of the corresponding second wiring.

In one embodiment of the invention, a thickness of the transparent conductive oxide patterns is between 0.042 μm and 0.08 μm.

In one embodiment of the invention, the transparent conductive oxide patterns located in the wiring region are spaced from a periphery of the active region by a first interval.

In one embodiment of the invention, the display panel further includes: at least one driving circuit disposed in a peripheral circuit region of the array substrate, wherein the wiring region is located between the active region and the peripheral circuit region, the first wirings and the second wirings are connected to the at least one driving circuit, and the transparent conductive oxide patterns are spaced from the at least one driving circuit by a second interval.

In one embodiment of the invention, the first wirings and the second wirings are arranged at equal intervals.

In one embodiment of the invention, the display medium includes an electrophoretic display thin film or an electrowetting display thin film.

The manufacturing method for a display panel of the invention includes the following steps. An array substrate is formed, including providing a substrate and forming a first metal layer, a first insulation layer, a semiconductor layer, a second metal layer, and a second insulation layer sequentially on the substrate, wherein the substrate has an active region and a wiring region at a periphery of the active region, and the first metal layer and the second metal layer extend from the active region to the wiring region to respectively define a plurality of first wirings and a plurality of second wirings. A plurality of transparent conductive oxide patterns on the second insulation layer and located in the wiring region is formed, wherein the transparent conductive oxide patterns respectively correspond to the second wirings, and an orthogonal projection of each of the transparent conductive oxide patterns onto the substrate overlaps with an orthogonal projection of the corresponding second wiring onto the substrate. A display medium is disposed on the array substrate.

In one embodiment of the invention, the transparent conductive oxide patterns are not connected to each other.

In one embodiment of the invention, a material of the transparent conductive oxide patterns is indium tin oxide or indium zinc oxide.

In one embodiment of the invention, an extension direction of each of the transparent conductive oxide patterns is identical to an extension direction of the corresponding second wiring.

In one embodiment of the invention, a width of the orthogonal projection of each of the transparent conductive oxide patterns onto the substrate is greater than a line width of the corresponding second wiring.

In one embodiment of the invention, a thickness of the transparent conductive oxide patterns is between 0.042 μm and 0.08 μm.

In one embodiment of the invention, the transparent conductive oxide patterns located in the wiring region are spaced from a periphery of the active region by a first interval.

In one embodiment of the invention, the manufacturing method for a display panel further includes disposing at least one driving circuit in a peripheral circuit region of the array substrate, wherein the wiring region is located between the active region and the peripheral circuit region, the first wirings and the second wirings are connected to the at least one driving circuit, and the transparent conductive oxide patterns are spaced from the at least one driving circuit by a second interval.

In one embodiment of the invention, the first wirings and the second wirings are arranged at equal intervals.

In one embodiment of the invention, the display medium includes an electrophoretic display thin film or an electrowetting display thin film.

In light of the above, the display panel of the invention includes the transparent conductive oxide patterns correspondingly disposed on the second wirings. Therefore, compared to a conventional insulation layer wherein a hole formed due to a process variation exposes the wirings to the atmosphere and further causes oxidization or erosion of the conductive lines, in the invention, disposing the transparent conductive oxide patterns effectively prevents and insulates the second wirings from being directly exposed to the atmosphere and further effectively enhances structural reliability of the display panel.

Other features and advantages of the invention will be further understood from the further technological features disclosed by the embodiments of the invention wherein there are shown and described embodiments of this invention, simply by way of illustration of modes best suited to carry out the invention.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1A is a partial top view of a display panel according to one embodiment of the invention.

FIG. 1B is a partial cross-sectional view of the display panel of FIG. 1A.

### DESCRIPTION OF THE EMBODIMENTS

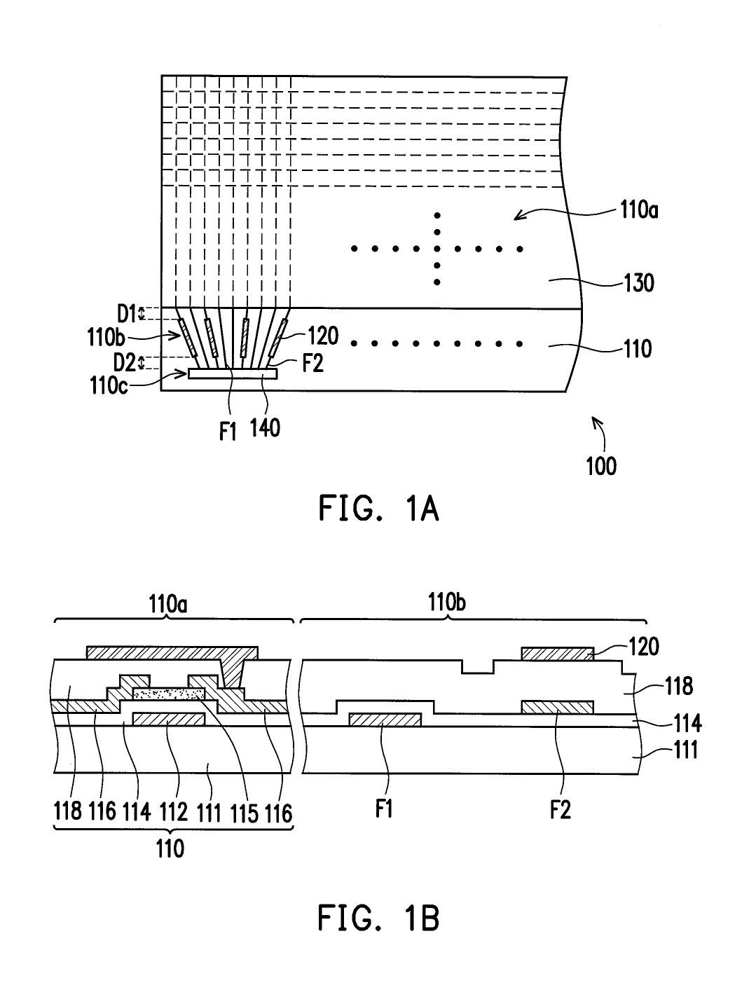

FIG. 1A is a partial top view of a display panel according to one embodiment of the invention. FIG. 1B is a partial cross-sectional view of the display panel of FIG. 1A. Referring to FIG. 1A and FIG. 1B, in the present embodiment, a display panel 100 includes an array substrate 110, a plurality of transparent conductive oxide patterns 120, and a display medium 130. The array substrate 110 includes a substrate 111, and a first metal layer 112, a first insulation layer 114, a semiconductor layer 115, a second metal layer 116, and a second insulation layer 118 sequentially disposed on the substrate 111. The substrate 111 has an active region 110a and a wiring region 110b at a periphery of the active region 110a. The first metal layer 112 and the second metal layer 116 extend from the active region 110a to the wiring region 110b to respectively define a plurality of first wirings F1 and a plurality of second wirings F2. The transparent conductive oxide patterns 120 are disposed on the second insulation layer 118 and located in the wiring region 110b, wherein the transparent conductive oxide patterns 120 respectively correspond to the second wirings F2. In addition, an orthogonal projection of each of the transparent conductive oxide patterns 120 onto the substrate 111 overlaps with an orthogonal projection of the corresponding second wiring F2 onto the substrate 111. The display medium 130 is disposed on the array substrate 110.

Specifically speaking, the array substrate 110 is an active element array substrate, for example, wherein the first metal layer 112 (equivalent to a gate electrode), the first insulation layer 114 (equivalent to a gate insulation layer), the semiconductor layer 115, the second metal layer 116 (equivalent to a source electrode and a drain electrode), and the second insulation layer 118 located in the active region 110a can define at least one thin film transistor. The first metal layer 112 extending from the active region 110a to the wiring region 110b is defined in the wiring region 110b as the first wirings F1. The second metal layer 116 extending from the active region 110a to the wiring region 110b is defined in the wiring region 110b as the second wirings F2. The first wirings F1 are separate from each other, the second wirings F2 are separate from each other, and the first wirings F1 and the second wirings F2 are arranged at equal intervals.

Moreover, the transparent conductive oxide patterns 120 of the present embodiment are disposed to respectively correspond to the second wirings F2. The orthogonal projection of the transparent conductive oxide patterns 120 onto the substrate 111 overlaps with the orthogonal projection of the corresponding second wirings F2 onto the substrate 111. In other words, the orthogonal projection of the transparent conductive oxide patterns 120 onto the substrate 111 does not overlap with an orthogonal projection of the first wirings F1 onto the substrate 111 at all. The display panel 100 of the present embodiment is disposed with the transparent conductive oxide patterns 120 for the following reason: According to FIG. 1B, the first wirings F1 are covered with a two-layer structure composed of the first insulation layer 114 and the second insulation layer 118. By contrast, the second wirings F2 are covered with a layer of the second insulation layer 118 only. Therefore, when a hole (e.g., a hole formed by chemical vapor deposition in a pre-process or a crack caused by a cutting process in a post-process) is formed in the second insulation layer 118 due to a process variation, the second wirings F2 adjacent to the second insulation layer 118 will be exposed to the atmosphere. Hence, in the present embodiment, protection by an additional layer is created by disposing the transparent conductive oxide patterns 120 above the second wirings F2, thereby effectively avoiding exposing the second wirings F2 to the atmosphere due to a process variation and further enhancing structural reliability of the display panel 100.

Furthermore, the transparent conductive oxide patterns 120 of the present embodiment are not connected to each other. In other words, a single transparent conductive oxide pattern 120 is correspondingly disposed on a single second wiring F2. As shown in FIG. 1A, an extension direction of a transparent conductive oxide patterns 120 is substantially identical to an extension direction of the corresponding second wiring F2 but is not limited thereto. A width of the orthogonal projection of the transparent conductive oxide patterns 120 onto the substrate 111 is substantially slightly greater than a line width of the corresponding second wirings F2, such that the second wirings F2 are effectively covered. A thickness of the transparent conductive oxide patterns 120 is preferably between 0.042 μm and 0.08 μm. A material of the transparent conductive oxide patterns 120 is indium tin oxide or indium zinc oxide, for example, but is not limited thereto. The aforementioned material is identical to a material of a film layer (e.g., a pixel electrode) requiring a mask step as a last step in a manufacturing process of the display panel 100. Therefore, it is not necessary to additionally increase a number of masks to be used in the manufacturing process, and a manufacturing cost of a product is thus not increased.

In addition, as shown in FIG. 1A, the display panel 100 of the present embodiment further includes at least one driving circuit 140 disposed in a peripheral circuit region 110c of the array substrate 110, wherein the wiring region 110b is located between the active region 110a and the peripheral circuit region 110c, and the first wirings F1 and the second wirings F2 are connected to the driving circuit 140. Herein, the transparent conductive oxide patterns 120 located in the wiring region 110b are spaced from a periphery of the active region 110a by a first interval D1, and the transparent conductive oxide patterns 120 are spaced from the driving circuit 140 by a second interval D2. In other words, the transparent conductive oxide patterns 120 are located in the wiring region 110b only and are spaced from the active region 110a and the peripheral circuit region 110c respectively by a distance to avoid a situation where the transparent conductive oxide patterns 120 are electrically connected to elements in the active region 110a and the driving circuit 140 and cause a signal short circuit.

Moreover, the display medium 130 of the present embodiment is an electrophoretic display thin film or an electrowetting display thin film, for example. In other words, the display panel 100 of the present embodiment is an electrophoretic display panel or an electrowetting display panel, for example. In other unillustrated embodiments, the display medium is a liquid crystal layer or other adequate display media and is not further limited here.

Regarding the manufacturing process, refer to FIGS. 1A and 1B again. First, an array substrate 110 is formed, includes providing a substrate 111 and forming a first metal layer 112, a first insulation layer 114, a semiconductor layer 115, a second metal layer 116, and a second insulation layer 118 sequentially on the substrate 111, wherein the substrate 111 has an active region 110a and a wiring region 110b at a periphery of the active region 110a, and the first metal layer 112 and the second metal layer 116 extend from the active region 110a to the wiring region 110b to respectively define first wirings F1 and second wirings F2. Next, a plurality of transparent conductive oxide patterns 120 is formed on the second insulation layer 118 and located in the wiring region 110b, wherein the transparent conductive oxide patterns 120 respectively correspond to the second wirings F2, and an orthogonal projection of each of the transparent conductive oxide patterns 120 onto the substrate 111 overlaps with an orthogonal projection of the corresponding second wiring F2 onto the substrate 111. Herein, the transparent conductive oxide patterns 120 located in the wiring region 110b are spaced from a periphery of the active region 110a by a first interval D1. Lastly, a display medium 130 is disposed on the array substrate 110. Note that the manufacturing method for the display panel 100 of the present embodiment further includes disposing at least one driving circuit 140 in a peripheral circuit region 110c of the array substrate 110, wherein the wiring region 110b is located between the active region 110a and the peripheral circuit region 110c, and the first wirings F1 and the second wirings F2 are connected to the driving circuit 140. In addition, the transparent conductive oxide patterns 120 are spaced from the driving circuit 140 by a second interval D2. In other words, the transparent conductive oxide patterns 120 of the present embodiment are located in the wiring region 110b only and are spaced from the active region 110a and the peripheral circuit region 110c respectively by a distance to avoid a situation where the transparent conductive oxide patterns 120 are electrically connected to elements in the active region 110a and the driving circuit 140 and cause a signal short circuit. Now, the manufacture of the display panel 100 is completed.

In summary of the above, the display panel of the invention includes the transparent conductive oxide patterns correspondingly disposed on the second wirings. Therefore, compared to a conventional insulation layer wherein a hole formed due to a process variation exposes the wirings to the atmosphere and further causes oxidization or erosion of the conductive lines, in the invention, disposing the transparent conductive oxide patterns effectively prevents and insulates the second wirings from being directly exposed to the atmosphere and further effectively enhances structural reliability of the display panel.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

1. A display panel, comprising:
an array substrate comprising a substrate, and a first metal layer, a first insulation layer, a semiconductor layer, a second metal layer, and a second insulation layer sequentially disposed on the substrate, wherein the substrate has an active region and a wiring region at a periphery of the active region, and the first metal layer and the second metal layer extend from the active region to the wiring region to respectively define a plurality of first wirings and a plurality of second wirings;
a plurality of transparent conductive oxide patterns disposed on the second insulation layer and located in the wiring region, wherein the transparent conductive oxide patterns respectively correspond to the second wirings, an orthogonal projection of each of the transparent conductive oxide patterns onto the substrate overlaps with an orthogonal projection of a corresponding second wiring onto the substrate, and an extension direction of each of the transparent conductive oxide patterns is identical to an extension direction of the corresponding second wiring; and
a display medium disposed on the array substrate.

2. The display panel as recited in claim 1, wherein the transparent conductive oxide patterns are not connected to each other.

3. The display panel as recited in claim 1, wherein a material of the transparent conductive oxide patterns is indium tin oxide or indium zinc oxide.

4. (canceled)

5. The display panel as recited in claim 1, wherein a width of the orthogonal projection of each of the transparent conductive oxide patterns onto the substrate is greater than a line width of the corresponding second wiring.

6. The display panel as recited in claim 1, wherein a thickness of each of the transparent conductive oxide patterns is between 0.042 μm and 0.08 μm.

7. The display panel as recited in claim 1, wherein the transparent conductive oxide patterns located in the wiring region are spaced from a periphery of the active region by a first interval.

8. The display panel as recited in claim 7, further comprising:
at least one driving circuit disposed in a peripheral circuit region of the array substrate, wherein the wiring region is located between the active region and the peripheral circuit region, the first wirings and the second wirings are connected to the at least one driving circuit, and the transparent conductive oxide patterns are spaced from the at least one driving circuit by a second interval.

9. The display panel as recited in claim 1, wherein the first wirings and the second wirings are arranged at equal intervals.

10. The display panel as recited in claim 1, wherein the display medium comprises an electrophoretic display thin film or an electrowetting display thin film.

11. A manufacturing method for a display panel, comprising:
forming an array substrate, comprising providing a substrate and forming a first metal layer, a first insulation layer, a semiconductor layer, a second metal layer, and a second insulation layer sequentially on the substrate, wherein the substrate has an active region and a wiring region at a periphery of the active region, and the first metal layer and the second metal layer extend from the active region to the wiring region to respectively define a plurality of first wirings and a plurality of second wirings;
forming a plurality of transparent conductive oxide patterns on the second insulation layer and located in the wiring region, wherein the transparent conductive oxide patterns respectively correspond to the second wirings, an orthogonal projection of each of the transparent conductive oxide patterns onto the substrate overlaps with an orthogonal projection of a corresponding second wiring onto the substrate, and an extension direction of each of the transparent conductive oxide patterns is identical to an extension direction of the corresponding second wiring; and
disposing a display medium on the array substrate.

12. The manufacturing method for the display panel as recited in claim 11, wherein the transparent conductive oxide patterns are not connected to each other.

13. The manufacturing method for the display panel as recited in claim 11, wherein a material of the transparent conductive oxide patterns is indium tin oxide or indium zinc oxide.

14. (canceled)

15. The manufacturing method for the display panel as recited in claim 11, wherein a width of the orthogonal projection of each of the transparent conductive oxide patterns onto the substrate is greater than a line width of the corresponding second wiring.

16. The manufacturing method for the display panel as recited in claim 11, wherein a thickness of each of the transparent conductive oxide patterns is between 0.042 μm and 0.08 μm.

17. The manufacturing method for the display panel as recited in claim 11, wherein the transparent conductive oxide patterns located in the wiring region are spaced from a periphery of the active region by a first interval.

18. The manufacturing method for the display panel as recited in claim 17, further comprising:
disposing at least one driving circuit in a peripheral circuit region of the array substrate, wherein the wiring region is located between the active region and the peripheral circuit region, the first wirings and the second wirings are connected to the at least one driving circuit, and the transparent conductive oxide patterns are spaced from the at least one driving circuit by a second interval.

19. The manufacturing method for the display panel as recited in claim 11, wherein the first wirings and the second wirings are arranged at equal intervals.

20. The manufacturing method for the display panel as recited in claim 11, wherein the display medium comprises an electrophoretic display thin film or an electrowetting display thin film.
